(19) United States
(12) Patent Application Publication
(10) Pub. No.: US 2005/0079731 A1
(43) Pub. Date: Apr. 14, 2005

(54) Plasma enhanced chemical vapor deposition methods and semiconductor processing methods of forming layers and shallow trench isolation regions

(75) Inventors: Sujit Sharan, Boise, ID (US); Gurtej S. Sandhu, Boise, ID (US)

Correspondence Address: WELLS ST. JOHN P.S., 601 W. FIRST AVENUE, SUITE 1300, SPOKANE, WA, 99201, US

(73) Assignee: Micron Technology, Inc.

(21) Appl. No.: 10/620,426

(22) Filed: Jul. 17, 2003

Related U.S. Application Data
(63) Continuation of application No. 09/652,534, filed on Aug. 31, 2000, now abandoned.

(51) Int. Cl. H01L 21/31; H01L 21/469

(52) U.S. Cl. 438/759; 438/788

(57) ABSTRACT

In accordance with an aspect of the invention, a substrate is placed within a plasma enhanced chemical vapor deposition reactor. A plurality of reactant gases are provided within the reactor proximate the substrate under high density plasma conditions effective to form a layer on the substrate. The conditions result in etching portions of the layer during its formation and thereby include a deposition to etch ratio of forming the layer. During the forming, the conditions are changed to change the deposition to etch ratio. In another aspect of the invention, the invention includes a semiconductor processing method of forming shallow trench isolation regions within a semiconductive substrate. Isolation trenches are formed within the semiconductive substrate. The substrate is provided within a plasma enhanced chemical vapor deposition reactor. A silane containing gas, an oxygen containing gas and an inert gas are injected into the reactor under high density plasma conditions effective to form a predominate SiO₂ comprising layer on the substrate to overfill the trenches. The conditions result in etching of portions of the layer during its formation and thereby includes a deposition to etch ratio of the forming SiO₂ comprising layer. During the forming, the conditions are changed to change the deposition to etch ratio.

### TECHNICAL FIELD

This invention relates to plasma enhanced chemical vapor deposition methods, to semiconductor processing methods of forming layers and shallow trench isolation regions, and to plasma enhanced chemical vapor deposition methods of forming SiO₂ comprising layers.

### BACKGROUND OF THE INVENTION

The processing of a semiconductor substrate to form integrated circuitry involves forming numerous layers over the substrate. Many of the layers are formed by a chemical vapor deposition (CVD) process involving placing the substrate within an elevated temperature environment provided by a reactor and providing reactant gases within the reactor. Successive layers are provided by successive CVD processes. However, characteristic temperatures of a typical CVD process may not be conducive to layers already formed over the substrate. For example, subsequent CVD processing of a substrate having an aluminum layer will cause unacceptable alloying of the aluminum into the substrate. Accordingly, plasma enhanced chemical vapor deposition (PECVD) techniques were developed that include forming a plasma within a reactor and using the energy of the plasma in an environment with a lower temperature to form the layers. Consequently, the PECVD process is more conducive to temperature sensitive layers than a non-plasma CVD process.

PECVD systems typically feature a parallel plate chamber within a reactor operated at a low pressure. A plasma source is used to generate a plasma field within the reactor, for example, radio-frequency-induced glow discharge, high density inductively coupled plasma, or other plasma sources within an environment of reactant gases provided within the reactor. Such PECVD systems are physically similar to plasma etch systems, and therefore, are capable of using the plasma field for etching a semiconductor substrate layer during the deposition processing.

One CVD and/or PECVD process forms shallow trench isolation regions within a substrate. A substrate having trench openings formed therein is provided within a reactor to form layers over the trenches thereby filling the same. However, as the semiconductor industry strives to increase the density of components per unit area of semiconductor substrate, the width of the trench openings continues to shrink such that depositing the layer within the trenches can be problematic.

FIGS. 1-2 illustrate the problem. A semiconductor substrate is generally indicated by numeral 10 and comprises a bulk substrate 12 having trenches 14 formed therein. The substrate is provided in a reactor (not shown) and a layer of insulative material 16 is deposited over the substrate 12 within the trenches 14. As layer 16 is deposited, the insulative material begins to build up over corners 17 of the trenches 14 forming facets or bread-loafing regions 18.

Referring to FIG. 2, as layer 16 continues to be deposited, the bread-loafing regions 18 begin to occlude the trench openings and form voids 20 within the portion of layer 16 that progresses into the trenches 14. These voids 20 can be detrimental to the performance of the isolation regions.

To overcome this problem, inductively coupled plasma reactors can be used with a bias being placed upon the substrate during deposition. The bias attracts ions in the plasma to bombard the layer 16 effectively producing a simultaneous deposition to sputter etching aspect of processing layer 16. The purpose and result of the sputter etching is to remove the bread-loafing regions 18 during deposition of layer 16, i.e., forming the bread-loafing regions 18, removing at least some of the is bread-loafing regions 18, forming the bread-loafing regions 18 and continuing the process until the trenches 14 are filled. The deposition to sputter etching aspect establishes a deposition to sputter etching ratio (also referred to as deposition to etch ratio and/or D:S ratio). An exemplary D/S ratio comprises a constant 6:1. This process can improve the deposition of layer 16 within the trenches 14.

However, such processing is not without its own drawbacks. FIG. 3 illustrates a problem (like numerals from the previously described embodiment are employed where appropriate with the difference being indicated with a suffix (b) or with different numerals). Consider corner sections 17 of substrate 12. The etching portion of the processing can cause corner sections 17 to be etched away from substrate 12 thereby changing the profile of trenches 14. Changing the profile of trenches 14 can detrimentally affect the performance of the isolation regions. Additionally, removed material from corners 17, designated with numeral 24, can settle within the trenches 14 inside layer 16. Since the removed material 24 is routinely not an insulative material as is characteristically used for isolation regions, the performance of the isolation regions is typically detrimentally affected.

### SUMMARY OF THE INVENTION

In accordance with an aspect of the invention, a substrate is placed within a plasma enhanced chemical vapor deposition reactor. A plurality of reactant gases are provided within the reactor proximate the substrate under high density plasma conditions effective to form a layer on the substrate. The conditions result in etching portions of the layer during its formation and thereby include a deposition to etch ratio of forming the layer. During the forming, the conditions are changed to change the deposition to etch ratio.

In another aspect of the invention, the invention includes a semiconductor processing method of forming shallow trench isolation regions within a semiconductive substrate. Isolation trenches are formed within the semiconductive substrate. The substrate is provided within a plasma enhanced chemical vapor deposition reactor. A silane containing gas, an oxygen containing gas and an inert gas are injected into the reactor under high density plasma conditions effective to form a predominate SiO₂ comprising layer on the substrate to overfill the trenches. The conditions result in etching of portions of the layer during its formation and thereby includes a deposition to etch ratio of the forming SiO₂ comprising layer. During the forming, the conditions are changed to change the deposition to etch ratio.

In yet another aspect of the invention, a substrate is placed within a plasma enhanced chemical vapor deposition reactor. A plurality of reactant gases are provided within the reactor proximate the substrate under plasma conditions. The plasma conditions are effective to form a substantially homogeneous layer of material on the substrate. While continuing to form the layer, a flow of at least one of the reactant gases is reduced during at least some of the forming.

### BRIEF DESCRIPTION OF THE DRAWINGS

Preferred embodiments of the invention are described below with reference to the following accompanying drawings.

FIG. 1 is a first embodiment of a fragmentary sectional view of a prior art semiconductor substrate discussed in the “background” section above.

FIG. 2 is a view of the FIG. 1 substrate fragment at a processing step subsequent to that shown in FIG. 1.

FIG. 3 is a second embodiment of a fragmentary sectional view of a prior art semiconductor substrate discussed in the “background” section above.

FIG. 4 is a fragmentary sectional view of a semiconductor substrate at one processing step in accordance with an embodiment of the invention.

FIG. 5 is a view of the FIG. 4 substrate fragment at a processing step subsequent to that shown in FIG. 4.

FIG. 6 is a view of the FIG. 4 substrate fragment at a processing step subsequent to that shown in FIG. 5.

FIG. 7 is a graphical representation of an aspect of the processing in accordance with one embodiment of the invention.

FIG. 8 is a graphical representation of an aspect of the processing in accordance with one embodiment of the invention.

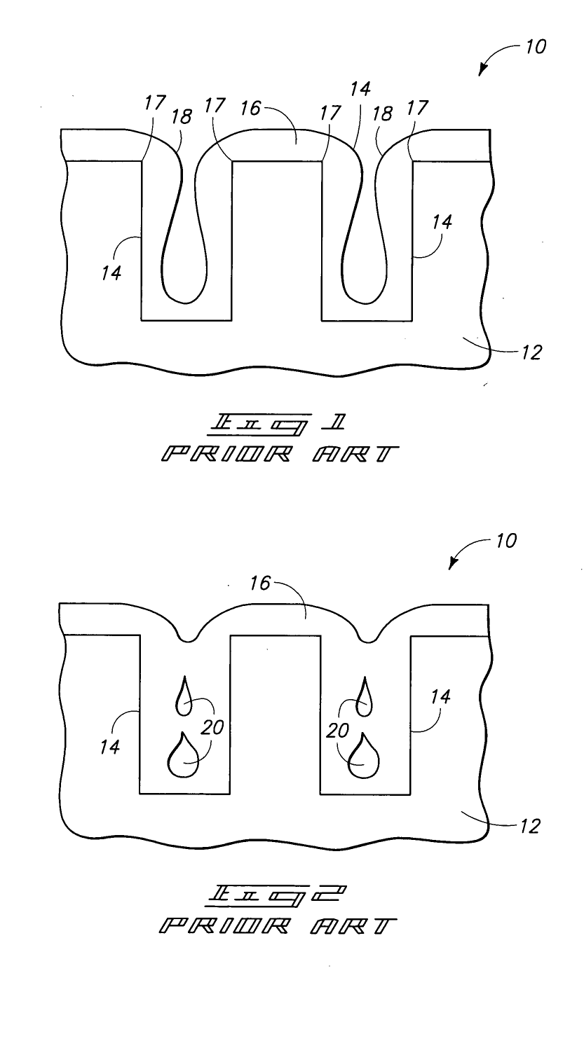

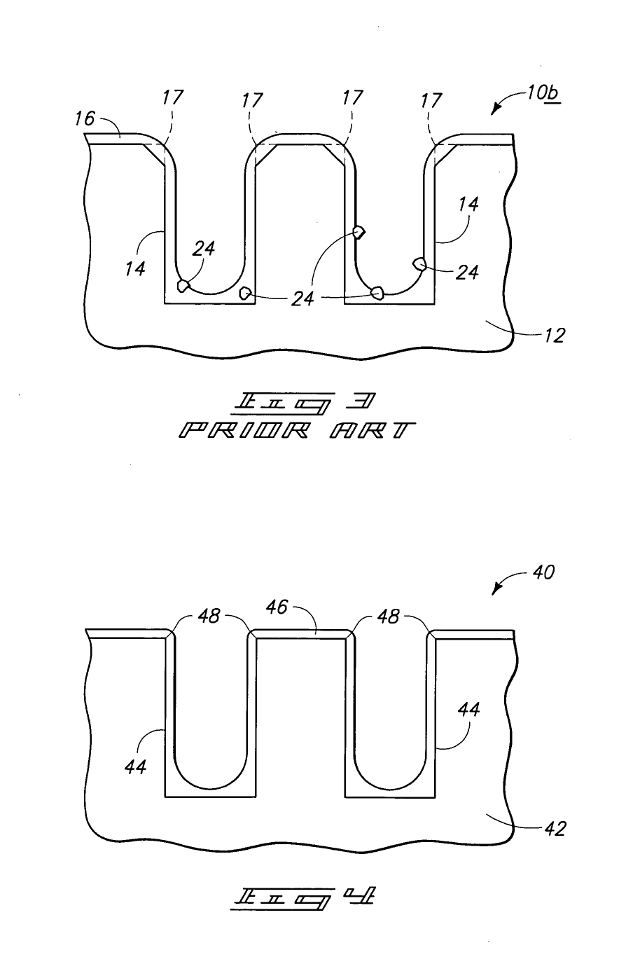

### DETAILED DESCRIPTION OF THE PREFERRED EMBODIMENTS

This disclosure of the invention is submitted in furtherance of the constitutional purposes of the U.S. Patent Laws “to promote the progress of science and useful arts” (Article 1, Section 8).

To aid in interpretation of the claims that follow, the terms “semiconductive substrate” and “semiconductor substrate” are defined to mean any construction comprising semiconductive material, including, but not limited to, bulk semiconductive materials such as a semiconductive wafer (either alone or in assemblies comprising other materials thereon), and semiconductive material layers (either alone or in assemblies comprising other materials). The term “substrate” refers to any supporting structure, including, but not limited to, the semiconductive substrates described above.

With reference to FIGS. 4-7, an embodiment of the method of the present invention is illustrated. This embodiment encompasses a semiconductor processing method, particularly a plasma enhanced chemical vapor deposition method of forming shallow trench isolation regions within a semiconductor substrate. Referring to FIG. 4, a semiconductor substrate 42 in process is indicated generally by reference numeral 40. An exemplary semiconductor substrate 42 comprises bulk substrate material, for example, monocrystalline silicon. Isolation trenches 44 are formed within the semiconductor substrate 42 by etching methods known in the industry, and include corners 48. The substrate 42 is provided within a plasma enhanced chemical vapor deposition reactor (not shown). An exemplary reactor comprises an inductively coupled plasma reactor capable of producing a high density plasma. In the context of this document, “high density” refers to a plasma having at least 109 ions/cm³ plasma density.

A plurality of reactant gases are provided within the reactor proximate the substrate 42 under plasma conditions, most preferably high density plasma conditions, effective to form a layer 46 on the substrate 42 and within trenches 44. An exemplary layer 46 comprises an electrically insulative material, for example, silicon dioxide. Exemplary reactant gases comprise a silane containing gas, an oxygen containing gas and an inert gas, for example, argon. An exemplary environment within the reactor includes a pressure preferably ranging from 0.1 mTorr to 50 mTorr, more preferably less than 5 mTorr, and a temperature of about 650° C. Exemplary flow rates of the reactant gases into the reactor comprise ranges of: argon at 0-300 sccm, oxygen at 100-300 sccm and silane at 20-200 sccm. The preferred high density plasma conditions result in etching of portions of the layer 46 during its formation and thereby include a deposition to etch ratio of the forming layer 46. An exemplary preferred initial D/S ratio of forming layer 46 is at least 7:1. This high deposition rate relative to the sputter etching rate is intended to keep outer corners 48 of the trenches covered by enough of forming layer 46 to protect such corners from being removed from the sputter etching action.

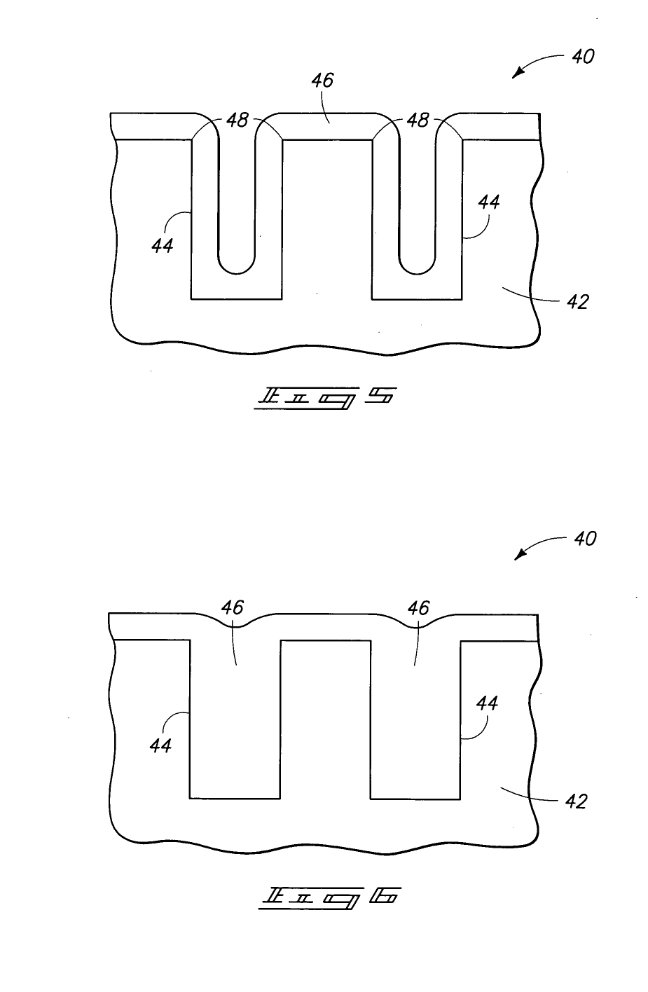

Referring to FIG. 5, deposition continues with the high density plasma conditions being changed during the forming to change the deposition to etch ratio. Most preferably, the deposition to etch ratio is decreased. Regardless, processing preferably continues to completely fill trenches 44, as shown in FIG. 6. Preferably, layer 46 as formed is substantially homogeneous throughout.

Changing of the conditions during the forming to change the deposition to etch ratio might occur by a number of manners. Such manners might include maintaining some parameters constant while changing one or more other parameters or changing a plurality of the operating parameters during the formation regardless. By way of example only, changing of the conditions might comprise changing a flow rate of at least one reactant gas to the reactor during formation, and/or changing at least one power setting during formation such as bias power on the substrate. Further, the changing conditions might comprise maintaining constant power settings while changing a flow rate of at least one reactant gas into the reactor during formation.

In one aspect, the invention contemplates providing conditions which begin with an environment providing a large deposition rate relative to an etch rate, thereafter decreasing the ratio, and thereafter increasing the ratio. Such provides but one example where the changing of the conditions reduces the deposition to etch ratio at least once during formation. Preferably, the deposition starts with substantially no etching during initial formation.

In one aspect of the invention, the invention contemplates changing the conditions during the forming to continuously vary the deposition to etch ratio throughout at least a majority of the forming. In one preferred implementation, changing the condition comprises continuously increasing the deposition to etch ratio at some point after a majority of the layer has been formed.

In the trench-filling example of forming SiO₂ under high density plasma conditions using a silane containing gas, an oxygen containing gas, and an inert gas, one aspect of the invention contemplates reducing a flow of at least one of the silane containing gas and the oxygen containing gas, or both, during the forming and continuing forming the layer. Such preferably has the effect of decreasing the deposition to etch ratio until such time as one or more of the flows might be increased. For example where the reactant gas silane is varied in such example, an exemplary high flow rate would be from about 60 sccm to about 150 sccm, with an exemplary low flow rate for silane being from about 20 sccm to about 60 sccm.

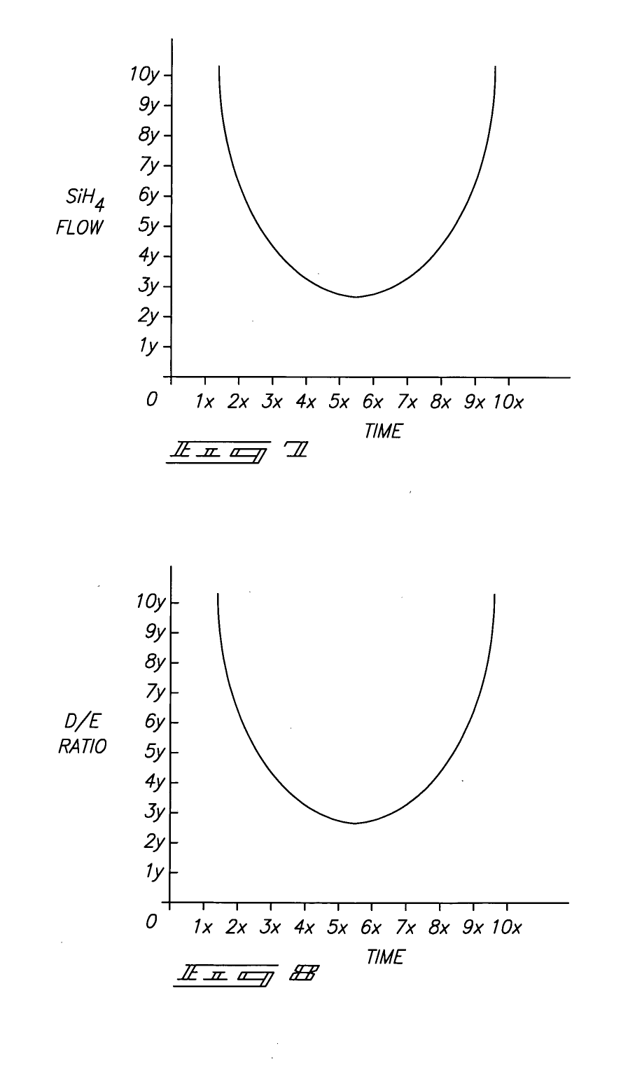

FIGS. 7-8 together graphically represent but one example embodiment of the present invention where silane flow is varied during formation. The process begins with an environment providing a large silane flow rate which corresponds, referring to FIG. 8, to providing a large deposition rate relative an etch rate. The deposition can start with substantially no etching of the layer during its initial formation. After this beginning, the silane flow rate is decreased which corresponds to decreasing the ratio. (i.e., at some point in time after the deposition begins, the etching increases relative to the deposition.) At some point in the example, the silane flow is increased, corresponding to an increase in the ratio, perhaps to a point which substantially eliminates etching while continuing the deposition. The illustrated example depicts a substantially continuous and parabolic profile, although any other profile is contemplated, such as by way of example, linearly, exponentially and logarithmically.

The invention was initially motivated and considered in the context of high density plasma deposition involving an etching aspect during the depositing. However, the invention also contemplates plasma enhanced chemical vapor depositing by placing a substrate within a plasma enhanced chemical vapor deposition reactor which may or may not be a high density plasma reactor, and may or may not be operated under high density plasma conditions. A plurality of reactant gases are then provided within the reactor proximate the substrate under plasma conditions effective to form a substantially homogeneous layer of material on the substrate. At some point in the process, a flow of at least one of the reactant gases is reduced during at least some of the forming and the layer is continued to be formed.

In compliance with the statute, the invention has been described in language more or less specific as to structural and methodical features. It is to be understood, however, that the invention is not limited to the specific features shown and described, since the means herein disclosed comprise preferred forms of putting the invention into effect. The invention is, therefore, claimed in any of its forms or modifications within the proper scope of the appended claims appropriately interpreted in accordance with the doctrine of equivalents.

1. A plasma enhanced chemical vapor deposition method comprising:
placing a substrate within a plasma enhanced chemical vapor deposition reactor;
providing a plurality of reactant gases within the reactor proximate the substrate under high density plasma conditions effective to form a layer on the substrate, the conditions resulting in etching of portions of the layer during its formation and thereby including a deposition to etch ratio of the forming layer;
changing the conditions during the forming to change the deposition to etch ratio; and
wherein the changing of the conditions reduces the deposition to etch ratio at least once during formation and subsequently increases the deposition to etch ratio during formation.

2. The method of claim 1 wherein changing the conditions comprises changing a flow rate of at least one reactant gas to the reactor during formation.

3. The method of claim 1 wherein changing the conditions comprises changing at least one power setting during formation.

4. The method of claim 1 wherein changing the conditions comprises changing a flow rate of at least one reactant gas to the reactor and changing at least one power setting during formation.

5. The method of claim 1 wherein changing the conditions comprises:
beginning with an environment providing a large deposition rate relative an etch rate;
after the beginning, decreasing the ratio; and
after decreasing the ratio, increasing the ratio.

6. The method of claim 1 wherein changing the conditions comprises changing at least one of bias power on the substrate and flow rate of at least one reactant gas into the reactor during formation.

7. The method of claim 1 wherein changing the conditions comprises maintaining constant power settings while changing a flow rate of at least one reactant gas into the reactor during formation.

8. The method of claim 1 wherein the layer comprises a predominate SiO₂ comprising layer and deposition starts with substantially no etching of the SiO₂ layer during its initial formation.

9-10. (canceled)

11. A plasma enhanced chemical vapor deposition method comprising:
placing a substrate within a plasma enhanced chemical vapor deposition reactor;
providing a plurality of precursor gases within the reactor proximate the substrate under high density plasma conditions effective to form a layer on the substrate, the conditions resulting in etching of portions of the layer during its formation and thereby including a deposition to etch ratio of the forming layer; and
changing the conditions during the forming to continuously vary the deposition to etch ratio throughout at least a majority of the forming.

12. The method of claim 11 wherein changing the conditions comprises continuously increasing the deposition to etch ratio at some point after a majority of the layer has been formed.

13. The method of claim 11 wherein changing the conditions comprises:
beginning with an environment providing a large deposition rate relative an etch rate;
after the beginning, decreasing the ratio;
after decreasing the ratio, increasing the ratio.

14. The method of claim 11 wherein changing the conditions comprises varying a flow rate of at least one precursor gas to the reactor during formation.

15. The method of claim 11 wherein changing the conditions comprises maintaining constant power settings during formation.

16. A semiconductor processing method of forming shallow trench isolation regions within a semiconductive substrate comprising:
forming isolation trenches within a semiconductive substrate;
providing the substrate with trenches within a plasma enhanced chemical vapor deposition reactor;
injecting at least a silane containing gas, an oxygen containing gas and an inert gas into the reactor under high density plasma conditions effective to form a predominate SiO₂ comprising layer on the substrate to overfill the trenches, the conditions resulting in etching of portions of the layer during its formation and thereby including a deposition to etch ratio of the forming SiO₂ comprising layer;
changing the conditions during the forming to change the deposition to etch ratio; and
wherein changing the conditions comprises substantially eliminating etching while continuing the deposition.

17. The method of claim 16 wherein changing the conditions comprise starting with a high deposition rate as compared to any etch rate, following with a reducing deposition to etch ratio and then following with an increasing deposition to etch ratio.

18. The method of claim 16 wherein changing the conditions comprises changing a flow rate of at least one of the silane containing gas, oxygen containing gas and inert gas.

19. The method of claim 16 wherein changing the conditions comprises changing a flow rate of the silane containing gas during formation.

20. The method of claim 16 wherein changing the conditions further comprises varying a bias power on the substrate during formation.

21. (canceled)

22. The method of claim 16 wherein the deposition starts with substantially no etching of the SiO₂ layer during its initial formation.

23. A plasma enhanced chemical vapor deposition method comprising:
placing a substrate within a plasma enhanced chemical vapor deposition reactor;
providing a plurality of reactant gases within the reactor proximate the substrate under plasma conditions effective to form a substantially homogeneous layer of material on the substrate; and
reducing a flow of at least one of the reactant gases during at least some of the forming and continuing forming the layer.

24. The method of claim 23 wherein the plasma conditions comprise etching conditions thereby providing an etch of the layer during at least some of its formation.

25. The method of claim 23 wherein at some point in time after the deposition begins, the etching increases relative to the deposition.

26. The method of claim 23 comprising maintaining substantially constant power settings during formation.

27. A plasma enhanced chemical vapor deposition method of forming a SiO₂ comprising layer on a semiconductor substrate, comprising:
placing a substrate within a plasma enhanced chemical vapor deposition reactor;
injecting at least a silane containing gas, an oxygen containing gas and an inert gas into the reactor under high density plasma conditions effective to form a predominate SiO₂ comprising layer on the substrate; and
reducing a flow of at least one of the silane containing gas and the oxygen containing gas during the forming and continuing forming the layer.

28. The method of claim 27 wherein reducing a flow comprises the silane containing gas.

29. The method of claim 27 wherein reducing a flow comprises the oxygen containing gas.

30. The method of claim 27 wherein reducing a flow comprises the silane containing gas and oxygen containing gas.

31. The method of claim 1 wherein the changing of the conditions comprises providing the changing simultaneously with the forming of the layer.

32. The method of claim 1 wherein the forming of the layer comprises forming a single layer.

33. The method of claim 1 wherein the forming of the layer comprises uninterrupted forming during the changing of the conditions.

34. The method of claim 16 wherein the changing of the conditions comprises providing the changing simultaneously with the forming of the predominate SiO₂ comprising layer.

35. The method of claim 16 wherein the forming of the predominate SiO₂ comprising layer comprises forming a single layer.

36. The method of claim 16 wherein the forming of the predominate SiO₂ comprising layer comprises uninterrupted forming during the changing of the conditions.

37. A plasma enhanced chemical vapor deposition method comprising:
placing a substrate within a plasma enhanced chemical vapor deposition reactor;
providing a plurality of reactant gases within the reactor proximate the substrate under high density plasma conditions effective to form a layer on the substrate, the conditions resulting in etching of portions of the layer during its formation and thereby including a deposition to etch ratio of the forming layer;
changing the conditions during the forming to change the deposition to etch ratio; and
wherein changing the conditions comprises:
beginning with an environment providing a large deposition rate relative an etch rate;
after the beginning, decreasing the ratio; and
after decreasing the ratio, increasing the ratio.

38. A semiconductor processing method of forming shallow trench isolation regions within a semiconductive substrate comprising:
forming isolation trenches within a semiconductive substrate;
providing the substrate with trenches within a plasma enhanced chemical vapor deposition reactor;
injecting at least a silane containing gas, an oxygen containing gas and an inert gas into the reactor under high density plasma conditions effective to form a predominate SiO₂ comprising layer on the substrate to overfill the trenches, the conditions resulting in etching of portions of the layer during its formation and thereby including a deposition to etch ratio of the forming SiO₂ comprising layer;
changing the conditions during the forming to change the deposition to etch ratio; and
wherein changing the conditions comprise starting with a high deposition rate as compared to any etch rate, following with a reducing deposition to etch ratio and then following with an increasing deposition to etch ratio.
